(19) United States
(12) Patent Application Publication
(10) Pub. No.: US 2025/0194199 A1
(43) Pub. Date: Jun. 12, 2025

(54) PITCH CONFIGURATION FOR BACK-END-OF-LINE WIRING

(71) Applicant: International Business Machines Corporation, Armonk, NY (US)

(72) Inventors: Brent A. Anderson, Jericho, VT (US); Nicholas Anthony Lanzillo, Wynantskill, NY (US); Albert M. Chu, Nashua, NH (US); David Wolpert, Poughkeepsie, NY (US); Ruilong Xie, Niskayuna, NY (US); Lawrence A. Clevenger, Saratoga Springs, NY (US)

(21) Appl. No.: 18/536,918

(22) Filed: Dec. 12, 2023

(51) Int. Cl. H01L 29/66; H01L 23/522; H01L 23/528; H01L 25/065; H01L 27/088; H01L 29/06; H01L 29/423; H01L 29/775; H01L 29/786

(52) U.S. Cl. CPC H10D 64/017; H01L 23/5226; H01L 23/528; H01L 25/0657; H10D 30/014; H10D 30/43; H10D 30/6735; H10D 30/6757; H10D 62/121; H10D 84/83; H01L 2225/06527

(57) ABSTRACT

A semiconductor structure comprises a first device layer, a second device layer, and a plurality of interconnect wiring levels between the first device layer and the second device layer. The plurality of interconnect wiring levels comprise a first interconnect wiring level adjacent the first device layer, wherein wires of the first interconnect wiring level are spaced apart from each other at a first pitch, a second interconnect wiring level adjacent the second device layer, wherein wires of the second interconnect wiring level are spaced apart from each other at a second pitch, and at least a third interconnect wiring level between the first interconnect wiring level and the second interconnect wiring level, wherein wires of the third interconnect wiring level are spaced apart from each other at a third pitch. The third pitch is greater than the first pitch and the second pitch.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming middle back-end-of-line (BEOL) wiring layers with different pitches.

In one embodiment, a semiconductor structure comprises a first device layer, a second device layer, and a plurality of interconnect wiring levels between the first device layer and the second device layer. The plurality of interconnect wiring levels comprise a first interconnect wiring level adjacent the first device layer, wherein wires of the first interconnect wiring level are spaced apart from each other at a first pitch, a second interconnect wiring level adjacent the second device layer, wherein wires of the second interconnect wiring level are spaced apart from each other at a second pitch, and at least a third interconnect wiring level between the first interconnect wiring level and the second interconnect wiring level, wherein wires of the third interconnect wiring level are spaced apart from each other at a third pitch. The third pitch is greater than the first pitch and the second pitch.

In another embodiment, a semiconductor structure comprises a first device layer comprising one or more transistors corresponding to a first doping type, a second device layer stacked over the first device layer and comprising one or more transistors corresponding to a second doping type, and a plurality of interconnect wiring levels stacked between the first device layer and the second device layer. The plurality of interconnect wiring levels comprise a first interconnect wiring level stacked over the first device layer, wherein wires of the first interconnect wiring level are spaced apart from each other at a first pitch, a second interconnect wiring level stacked over the first interconnected wiring level and under the second device layer, wherein wires of the second interconnect wiring level are spaced apart from each other at a second pitch, and at least a third interconnect wiring level stacked between the first interconnect wiring level and the second interconnect wiring level, wherein wires of the third interconnect wiring level are spaced apart from each other at a third pitch. The third pitch is greater than the first pitch and the second pitch.

In another embodiment, a semiconductor structure comprises a first device layer, a second device layer, and at least three interconnect wiring levels respectively stacked between the first device layer and the second device layer. Wires of an uppermost interconnect wiring level of the at least three interconnect wiring levels and wires of a lowermost interconnect wiring level of the at least three interconnect wiring levels have a minimum pitch which is smaller than a minimum pitch of wires of at least one remaining interconnect wiring level of the at least three interconnect wiring levels. The at least one remaining interconnect wiring level is stacked between the uppermost interconnect wiring level and the lowermost interconnect wiring level.

These and other features and advantages of embodiments described herein will become more apparent from the accompanying drawings and the following detailed description.

### BRIEF DESCRIPTION OF THE DRAWINGS

FIG. 1 depicts a cross-sectional view of a semiconductor structure including middle BEOL wiring layers with different pitches between first and second device layers, according to an embodiment of the invention.

FIG. 2A depicts a cross-sectional view of a semiconductor structure including middle BEOL wiring layers with different pitches between first and second device layers and various via connections, according to an embodiment of the invention.

FIG. 2B depicts a cross-sectional view of a semiconductor structure including middle BEOL wiring layers with different pitches between first and second device layers and various via connections, according to an embodiment of the invention.

FIG. 2C depicts a cross-sectional view of a semiconductor structure including middle BEOL wiring layers with different pitches between first and second device layers and various via connections, according to an embodiment of the invention.

FIG. 3 depicts a cross-sectional view of middle BEOL wiring layers with different pitches, according to an embodiment of the invention.

FIG. 4 depicts a cross-sectional view of middle BEOL wiring layers with different pitches and various via connections, according to an embodiment of the invention.

### DETAILED DESCRIPTION

Illustrative embodiments of the invention may be described herein in the context of illustrative methods for forming middle BEOL wiring layers with different pitches between first and second device layers, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40%) for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although some embodiments of the present invention are discussed in connection with nanosheet stacks, the embodiments of the present invention are not necessarily limited thereto, and may similarly apply to nanowire stacks.

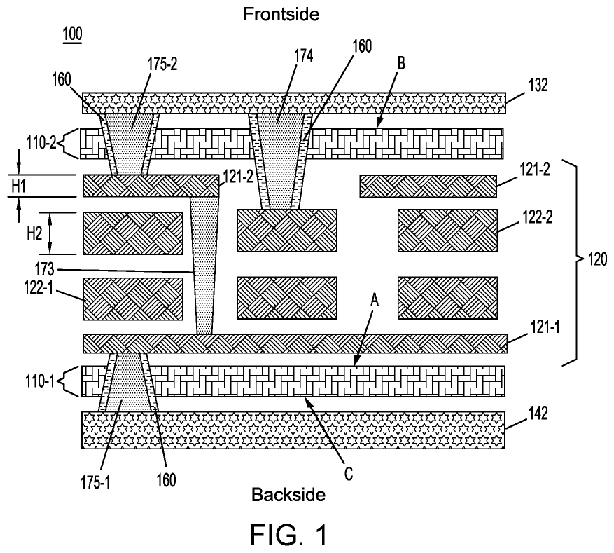

FIG. 1 depicts a cross-sectional view of a semiconductor structure 100 including a middle BEOL wiring configuration 120 with interconnect wiring layers 121-1, 121-2, 122-1 and 122-2 between a first device layer 110-1 and a second device layer 110-2 (collectively first and second device layers 110). The interconnect wiring layers 121-1 and 121-2 have different pitches from interconnect wiring layers 122-1, 122-2 and are formed in for, example, a dielectric layer (not shown) comprising, for example, silicon oxide (SiOₓ) (where x is for example, 2, 1.99 or 2.01), silicon oxycarbide (SiOC), silicon oxycarbonitride (SiOCN) or some other dielectric material.

In a non-limiting example embodiment, the first and second device layers 110 comprise stacked nanosheet transistors comprising a plurality of gate structures alternately stacked with a plurality of channel layers, and source/drain regions disposed between the nanosheet stacks comprising the gate structures and channel layers. However, the embodiments are not limited to stacked nanosheet transistors in the first and second device layers 110, and may comprise other types of transistors including, but not necessarily limited to, planar FETs, vertical transport FETs (VTFETs) or other types of transistors.

In an illustrative embodiment, the first device layer 110-1 is formed, followed by formation of the middle BEOL wiring configuration 120. A layer of semiconductor material (e.g., silicon, III-V, II-V compound semiconductor materials or other like semiconductor materials) is bonded to the middle BEOL wiring configuration 120, and the second device layer 110-2 is formed.

The middle BEOL wiring configuration 120 comprises three or more levels of interconnect wiring located between the first device layer 110-1 and the second device layer 110-2. Uppermost and lowermost (top and bottom) interconnect wiring levels 121-2 and 121-1 have a smaller pitch between wires than one or more interconnect wiring levels 122-1 and 122-2 between the uppermost and lowermost (top and bottom) interconnect wiring levels 121-2 and 121-1. For example, the uppermost and lowermost interconnect wiring levels 121-2 and 121-1 have a relatively smaller pitch between wires to facilitate connections of the wires to respective first and second device layers 110, while one or more interconnect wiring levels 122-1 and 122-2 between the uppermost and lowermost interconnect wiring levels 121-2 and 121-1 have a relatively larger pitch between wires to facilitate use for power delivery and longer distance clock, bus and signal wiring.

A frontside BEOL metallization structure includes frontside BEOL metallization layers 132 formed on the second device layer 110-2. The frontside BEOL metallization layers 132 can comprise, for example, wiring that is present on a chip, including, for example, multiple metal levels corresponding to circuit wiring, bussing, power distribution, input-output (I/O), etc. In illustrative embodiments, the frontside BEOL metallization structure includes frontside BEOL interconnects formed on the frontside BEOL metallization layers 132. The frontside BEOL metallization layers 132 contact the frontside BEOL interconnects. A carrier wafer is bonded to the frontside BEOL interconnects. The frontside BEOL interconnects include various BEOL interconnect structures which may electrically connect to one or more frontside BEOL metallization layers 132. A carrier wafer is formed over the frontside BEOL interconnects using a wafer bonding process, such as dielectric-to-dielectric bonding. The carrier wafer comprises semiconductor material including, but not limited to, silicon (Si), III-V, II-V compound semiconductor materials or other like semiconductor materials. In addition, multiple layers of the semiconductor materials can be used as the semiconductor material of the carrier wafer. Using the carrier wafer, the semiconductor structure 100 may be “flipped” (e.g., rotated 180 degrees) so that the structure is inverted for backside processing.

A backside BEOL metallization structure includes backside BEOL metallization layers 142. The backside BEOL metallization layers 142 can comprise, for example, backside power rails or other voltage or signal sources.

Referring to FIG. 1, as shown by the arrow A, tops of gates of transistors in the first device layer 110-1 are adjacent to the middle BEOL wiring configuration 120, as shown by the arrow B, tops of gates of transistors in the second device layer 110-2 are adjacent to the frontside BEOL metallization layers 132, and as shown by the arrow C, bottoms of gates of transistors in the first device layer 110-1 are adjacent to the backside BEOL metallization layers 142.

As used herein, “frontside” or “first side” refers to a side corresponding to the frontside BEOL metallization layers 132. As used herein, “backside” or “second side” refers to a side corresponding to the backside BEOL metallization layers 142 (e.g., opposite the “frontside”).

As noted hereinabove, the first and second device layers 110 can comprise, for example, stacked nanosheet transistors. For example, the first device layer 110-1 may comprise stacked nanosheet transistors having a first doping type (e.g., p-type) and the second device layer 110-2 may comprise stacked nanosheet transistors having a second doping type (e.g., n-type). Although described in terms of stacked nanosheet transistors, first and second device layers 110 are not limited thereto, and may comprise different types of devices such as, but not necessarily limited to, other types of transistors (e.g., planar transistors, FinFETs, VTFETs), capacitors, and/or other devices.

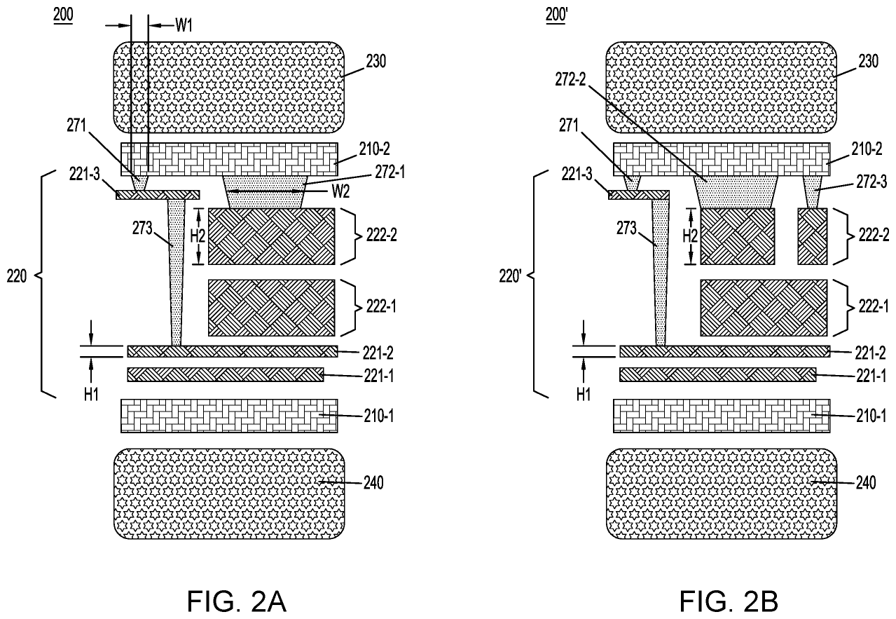

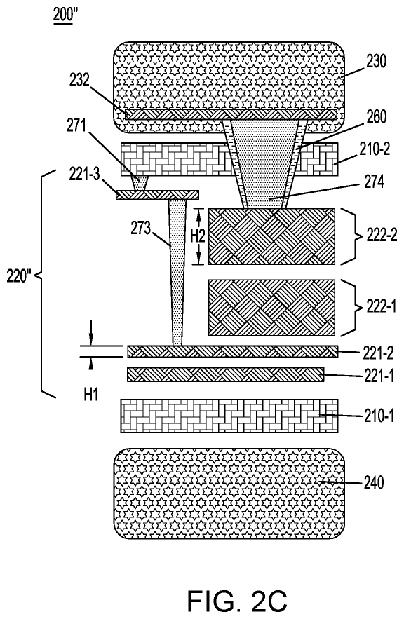

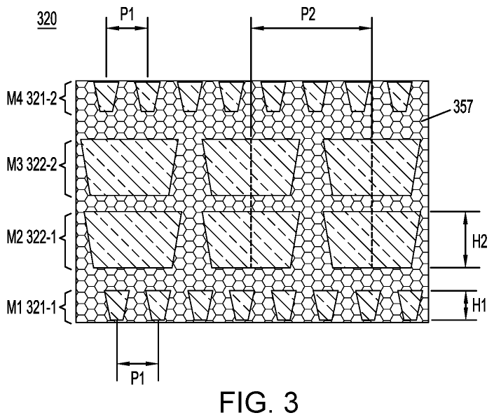

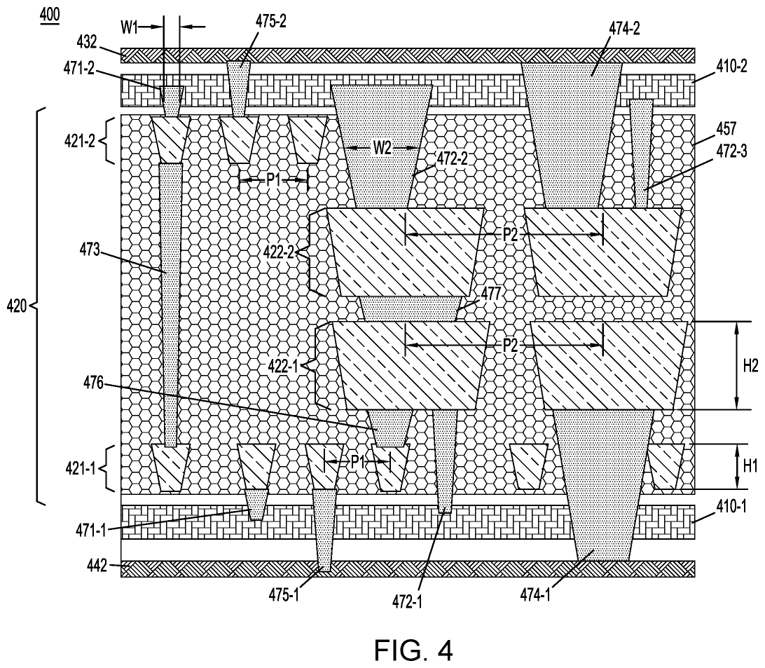

Referring to the semiconductor structures 200, 200′ and 200″ in FIGS. 2A-2C, the middle BEOL wiring configuration 320 in FIG. 3 and to the semiconductor structure 400 in FIG. 4, where like numerals represent the same or similar elements, middle BEOL wiring configurations 220, 220′, 220″, 320 and 420 are shown. The middle BEOL wiring configurations 220, 220′ and 220″ are between first and second device layers 210-1 and 210-2 (collectively first and second device layers 210). The first and second device layers 210 may be the same as or similar to the first and second device layers 110. A frontside BEOL metallization structure 230 is formed over the second device layer 210-2 and a backside BEOL metallization structure 240 is formed under the first device layer 210-1.

The middle BEOL wiring configuration 420 is between first and second device layers 410-1 and 410-2 (collectively first and second device layers 410). The first and second device layers 410 may be the same as or similar to the first and second device layers 110 and/or 210. A frontside BEOL metallization layer 432 (which may the same as or similar to the frontside BEOL metallization layer 132) and a backside BEOL metallization layer 442 (which may the same as or similar to the backside BEOL metallization layer 142) are also shown in FIG. 4. FIG. 3 does not show first and second device layers or frontside and backside BEOL metallization structures.

The middle BEOL wiring configurations 320 and 420 in FIGS. 3 and 4 comprise a plurality of interconnect wiring levels 321-1, 321-2, 322-1, 322-2, 421-1, 421-2, 422-1 and 422-2. Wires of a lowermost (bottom) interconnect wiring level 321-1/421-1 (e.g., adjacent the first device layer 410-1) are spaced apart from each other at a first pitch P1. Wires of an uppermost (top) interconnect wiring level 321-2/421-2 (e.g., adjacent the second device layer 410-2) are spaced apart from each other at the first pitch P1. Wires of interconnect wiring levels 322-1, 322-2/422-1, 422-2 between the lowermost (bottom) interconnect wiring level 321-1/421-1 and the uppermost (top) interconnect wiring level 321-2/421-2 are spaced apart from each other at a second pitch P2, which is larger than the first pitch P1. In illustrative embodiments, the pitches P1 and P2 can refer to minimum pitches between wires for each corresponding interconnect wiring level. Each of the wires in a given interconnect wiring level may be spaced from each other at the same pitch (e.g., P1 or P2). In illustrative embodiments, pitch P2 may be at least three times pitch P1. In some embodiments, the pitch of the wires in the lowermost (bottom) interconnect wiring level 321-1/421-1 can be different from the pitch of the wires in the uppermost (top) interconnect wiring level 321-2/421-2, as long as the pitches of the wires in the lowermost (bottom) interconnect wiring level 321-1/421-1 and the uppermost (top) interconnect wiring level 321-2/421-2 are less than the pitches in the interconnect wiring levels 322-1, 322-2/422-1, 422-2. In some embodiments, the pitch of the wires in the interconnect wiring level 322-1/422-1 can be different from the pitch of the wires in the interconnect wiring level 322-2/422-2, as long as the pitches of the wires in the interconnect wiring levels 322-1/422-1 and 322-2/422-2 are greater than the pitches in the lowermost and uppermost interconnect wiring levels 321-1, 321-2/421-1, 421-2.

The middle BEOL wiring configurations 120, 220, 220′, 220″, 320 and 420 in FIGS. 1-4 comprise interconnect wiring levels 121-1, 121-2, 221-1, 221-2, 321-1, 321-2, 421-1 and 421-2 with a smaller pitch (e.g., pitch P1) and a smaller height (e.g., height H1) when compared with interconnect wiring levels 122-1, 122-2, 222-1, 222-2, 322-1, 322-2, 422-1 and 422-2 with a larger pitch (e.g., pitch P2) and a larger height (e.g., height H2). Wires of a lowermost (bottom) interconnect wiring level (e.g., 121-1, 221-1, 321-1 and 421-1) adjacent a first device layer (e.g., 110-1, 210-1, 410-1) and wires of an uppermost (top) interconnect wiring level (e.g., 121-2, 221-3, 321-2 and 421-2) adjacent a second device layer (e.g., 110-2, 210-2, 410-2) are spaced apart from each other at a smaller first pitch (e.g., pitch P1) and have a smaller height (e.g., height H1) than wires of one or more interconnect wiring layers (e.g., 122-1, 122-2, 222-1, 222-2, 322-1, 322-2, 422-1, 422-2) between the uppermost and lowermost interconnect wiring layers. The wires of the one or more interconnect wiring layers (e.g., 122-1, 122-2, 222-1, 222-2, 322-1, 322-2, 422-1, 422-2) have a larger pitch (e.g., pitch P2) and a larger height (e.g., height H2). In illustrative embodiments, the height H1 can refer to a maximum height and the height H2 can refer a minimum height for wires in each corresponding interconnect wiring level. Alternatively, each of the wires in a given interconnect wiring level may have the same height (e.g., H1 or H2). In illustrative embodiments, the height H2 may be at least three times height H1.

As can be seen in FIGS. 2A-2C, there may be one or more interconnect wiring layers (e.g., interconnect wiring layer 221-2) between the uppermost and lowermost interconnect wiring layers that have the same pitch (e.g., pitch P1) and same height (e.g., height H1) as the uppermost and lowermost interconnect wiring layers.

Referring to FIGS. 1, 2A-2C and FIG. 4, there are various via configurations connecting device layers to interconnect wiring layers, connecting interconnect wiring layers to each other and connecting BEOL metallization layers to interconnect wiring layers. For example, a via 471-1 directly connects the first device layer 410-1 to a wire of the lowermost interconnect wiring layer 421-1. Similarly, a via 271 directly connects a second device layer 210-2 to one or more wires of the uppermost interconnect wiring layer 221-3. A via 472-1 directly connects the first device layer 410-1 to a wire of interconnect wiring layer 422-1, and a via 472-2 directly connects the second device layer 410-2 to a wire of interconnect wiring layer 422-2. Similarly, vias 272-1, 272-2 and 272-3 directly connect a second device layer 210-2 to one or more wires of interconnect wiring layer 222-2. A via 472-3 directly connects the second device layer 410-2 to interconnect wiring layer 422-2.

As shown in FIGS. 1 and 2A-2C, a via 173 directly connects interconnect wiring layer 121-1 to interconnect wiring layer 121-2 and a via 273 directly connects interconnect wiring layer 221-3 to interconnect wiring layer 221-2. In FIG. 4, a via 473 directly connects the uppermost interconnect wiring layer 421-2 to the lowermost interconnect wiring layer 421-1. Also referring to FIG. 4, a via 476 directly connects the lowermost interconnect wiring layer 421-1 to interconnect wiring layer 422-1, and a via 477 directly connects interconnect wiring layer 422-1 to interconnect wiring layer 422-2.

As shown in FIGS. 1 and 2C, a via 174/274 directly connects frontside BEOL metallization layer 132/232 to interconnect wiring layer 122-2/222-2. FIGS. 1 and 2C further illustrate dielectric layer 160/260 isolating the via 174/274 from the second device layer 110-2/210-2. At least a portion of the dielectric layer 160/260 may comprise a shallow trench isolation (STI) region formed in the second device layer 110-2/210-2. In FIG. 4, a via 474-2 directly connects frontside BEOL metallization layer 432 to interconnect wiring layer 422-2, and a via 474-1 directly connects backside BEOL metallization layer 442 to interconnect wiring layer 422-1. Although not shown in FIG. 4, the via 474-1 is also isolated by a dielectric layer from the second device layer 410-2. Also referring to FIGS. 1 and 4, a via 175-2/475-2 directly connects frontside BEOL metallization layer 132/432 to the uppermost interconnect wiring layer 121-2/421-2, and a via 175-1/475-1 directly connects backside BEOL metallization layer 142/442 to the lowermost interconnect wiring layer 121-1/421-1. FIG. 1 further illustrates dielectric layers 160 isolating the vias 175-1 and 175-2 from the first and second device layers 110-1 and 110-2. Although not shown in FIG. 4, the via 475-1 and 475-2 are also isolated by dielectric layers from the first and second device layers 410-1 and 410-2.

In illustrative embodiments, the widths of the vias contacting the interconnect wiring layers corresponding to the larger pitches (e.g., pitch P2) are larger than the widths of the vias contacting the interconnect wiring layers corresponding to the smaller pitches (e.g., pitch P1). For example, the width W1 of the vias 271 and 471-2 contacting the uppermost interconnect wiring levels 221-3 and 421-2 is smaller than the width W2 of the vias 272-1 and 472-2 contacting the interconnect wiring levels 222-2 and 422-2. In some embodiments, the widths of the vias contacting the interconnect wiring layers corresponding to the larger pitches are at least three times the widths of the vias contacting the interconnect wiring layers corresponding to the smaller pitches.

The vias 173, 174, 175-1, 175-2, 271, 272-1, 272-2, 272-3, 273, 274, 471-1, 471-2, 472-1, 472-2, 472-3, 473, 474-1, 474-2, 475-1, 475-2, 476 and 477 in dielectric layers (e.g., dielectric layers 160/260 and 457). According to an embodiment, masks are formed on parts of a dielectric layer, and exposed portions of the dielectric layers corresponding to where openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF₃ based chemistry.

Metal layers are deposited in the openings to form the vias. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), liquid source misted chemical deposition (LSMCD), sputtering and/or plating, followed by a planarization process such as, chemical mechanical planarization (CMP) to remove excess portions of the metal layers from on top of dielectric layers.

Referring to FIG. 3, metallization levels M1 and M4 correspond to smaller (e.g., tight) pitches for connections to device layers (e.g., first and second device layers 110-1 and 110-2, 210-1 and 210-2, 410-1 and 410-2. Metallization levels M2 and M3 correspond to larger pitches for connections to global power distribution elements (e.g., power rails). For example, in illustrative embodiments, backside power delivery network (BSPDN) layers are formed on a backside power rail. BSPDN layers include various BSPDN structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents BEOL routing congestion, resulting in power performance benefits.

The plurality of interconnect wiring levels for respective ones of the middle BEOL wiring configurations 120, 220, 220′, 220″, 320 and 420 in FIGS. 1-4 are on respective integrated chips. For example, the plurality of interconnect wiring levels for the middle BEOL wiring configuration 120 are on one integrated chip, the plurality of interconnect wiring levels for the middle BEOL wiring configurations 220, 220′ and 220″ are on first, second and third integrated chips, respectively, the plurality of interconnect wiring levels for the middle BEOL wiring configuration 320 are on one integrated chip and the plurality of interconnect wiring levels for the middle BEOL wiring configuration 420 are on one integrated chip. As used herein, an “integrated chip” refers to a single chip that has not been bonded to another chip at any of the interconnect wiring levels. In other words, the middle BEOL wiring configurations 120, 220, 220′, 220″, 320 and 420 are not the result of bonding any chips or interconnect wiring layers together.

The wires of the interconnect wiring levels 121-1, 121-2, 221-1, 221-2, 221-2, 321-1, 321-2, 421-1 and 421-2, and the wires of the interconnect wiring levels 122-1, 122-2, 222-1, 222-2, 322-1, 322-2, 422-1 and 422-2 are formed in portions of middle inter-layer dielectric (ILD) layers (e.g., middle ILD layers 357 and 457). The middle ILD layers 357 and 457 are deposited using deposition techniques such as, for example, CVD, PECVD, RFCVD, PVD, ALD, MBD, PLD, and/or LSMCD, followed by a planarization process, such as, CMP. The middle ILD layers 357 and 457 may comprise, for example, SiOₓ, SiOC, SiOCN or some other dielectric material. A middle ILD layer for FIG. 1 and FIGS. 2A-2C is not shown. In forming the wires, one or more trenches are formed in a corresponding middle ILD layer. Trenches may be opened in a middle ILD layer using, for example, lithography followed by RIE. The wires are formed by filling the one or more trenches with conductive material, such as, for example, electrically conductive material including, but not necessarily limited to, tungsten, cobalt, zirconium, tantalum, titanium, aluminum, ruthenium, and/or copper. A liner layer (not shown) including, for example, titanium and/or titanium nitride, may be formed on side and bottom surfaces of the trenches before filling the trenches with the conductive material. Deposition of the conductive material can be performed using one or more deposition techniques, including, but not necessarily limited to, CVD, PECVD, PVD, ALD, MBD, PLD, LSMCD, and/or spin-on coating, followed by planarization using a planarization process, such as, for example, CMP.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming middle BEOL wiring layers with different pitches between first and second device layers. In the illustrative embodiments, small pitch interconnect lines are advantageously formed on top of large pitch interconnect lines. The presence of small pitch interconnect lines over large pitch interconnect lines advantageously enables formation of simplified contacts to middle BEOL layers. In addition, the embodiments provide techniques and structures for forming vias directly connecting an upper small pitch interconnect wiring layer to a lower interconnect wiring layer. Further, another advantage of the illustrative embodiments is that backside BEOL wiring directly connected to the middle BEOL wiring (e.g., through vias 175-1, 475-1, 474-1) can eliminate the need for backside BEOL wiring that is directly connected to devices in the device layers. Although connections between backside BEOL layers and device layers can be included, backside BEOL wiring connections to middle BEOL levels can be used in place of backside BEOL to device connections, thereby simplifying configurations and lowering costs.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a first device layer;
a second device layer; and
a plurality of interconnect wiring levels between the first device layer and the second device layer, wherein the plurality of interconnect wiring levels comprise:
a first interconnect wiring level adjacent the first device layer, wherein wires of the first interconnect wiring level are spaced apart from each other at a first pitch;
a second interconnect wiring level adjacent the second device layer, wherein wires of the second interconnect wiring level are spaced apart from each other at a second pitch; and
at least a third interconnect wiring level between the first interconnect wiring level and the second interconnect wiring level, wherein wires of the third interconnect wiring level are spaced apart from each other at a third pitch, and the third pitch is greater than the first pitch and the second pitch.

2. The semiconductor structure of claim 1, wherein the second device layer is stacked above the first device layer.

3. The semiconductor structure of claim 1, further comprising:
a backside back-end-of-line metallization structure under the first device layer; and
a frontside back-end-of-line metallization structure over the second device layer.

4. The semiconductor structure of claim 1, wherein the first pitch is the same as the second pitch.

5. The semiconductor structure of claim 1, wherein the third pitch is at least three times at least one of the first pitch and the second pitch.

6. The semiconductor structure of claim 5, further comprising:
a first via connecting the second device layer to the third interconnect wiring level; and
a second via connecting the second device layer to the second interconnect wiring level;
wherein a width of the first via is at least three times a width of the second via.

7. The semiconductor structure of claim 1, further comprising a via connecting the second device layer to the third interconnect wiring level.

8. The semiconductor structure of claim 1, further comprising a via connecting the second device layer to the second interconnect wiring level.

9. The semiconductor structure of claim 1, further comprising a via connecting the second interconnect wiring level to the first interconnect wiring level.

10. The semiconductor structure of claim 1, wherein the plurality of interconnect wiring levels are on a same integrated chip.

11. The semiconductor structure of claim 1, wherein a height of the wires of the third interconnect wiring level is greater than a height of the wires of the first interconnect wiring level and a height of the wires of the second interconnect wiring level.

12. A semiconductor structure comprising:
a first device layer comprising one or more transistors corresponding to a first doping type;
a second device layer stacked over the first device layer and comprising one or more transistors corresponding to a second doping type; and
a plurality of interconnect wiring levels stacked between the first device layer and the second device layer, wherein the plurality of interconnect wiring levels comprise:
a first interconnect wiring level stacked over the first device layer, wherein wires of the first interconnect wiring level are spaced apart from each other at a first pitch;
a second interconnect wiring level stacked over the first interconnected wiring level and under the second device layer, wherein wires of the second interconnect wiring level are spaced apart from each other at a second pitch; and
at least a third interconnect wiring level stacked between the first interconnect wiring level and the second interconnect wiring level, wherein wires of the third interconnect wiring level are spaced apart from each other at a third pitch, and the third pitch is greater than the first pitch and the second pitch.

13. The semiconductor structure of claim 12, further comprising:
a backside back-end-of-line metallization structure under the first device layer; and
a frontside back-end-of-line metallization structure over the second device layer.

14. The semiconductor structure of claim 13, further comprising a via connecting the second device layer to the third interconnect wiring level.

15. The semiconductor structure of claim 13, further comprising a via connecting the second device layer to the second interconnect wiring level.

16. The semiconductor structure of claim 13, further comprising a via connecting the second interconnect wiring level to the first interconnect wiring level.

17. The semiconductor structure of claim 13, wherein the plurality of interconnect wiring levels further comprise a fourth interconnect wiring level stacked over the third interconnect wiring level and between the first interconnect wiring level and the second interconnect wiring level, wherein wires of the fourth interconnect wiring level are spaced apart from each other at a fourth pitch, and the fourth pitch is greater than the first pitch and the second pitch.

18. A semiconductor structure comprising:
a first device layer;
a second device layer; and
at least three interconnect wiring levels respectively stacked between the first device layer and the second device layer;
wherein wires of an uppermost interconnect wiring level of the at least three interconnect wiring levels and wires of a lowermost interconnect wiring level of the at least three interconnect wiring levels have a minimum pitch which is smaller than a minimum pitch of wires of at least one remaining interconnect wiring level of the at least three interconnect wiring levels; and
wherein the at least one remaining interconnect wiring level is stacked between the uppermost interconnect wiring level and the lowermost interconnect wiring level.

19. The semiconductor structure of claim 18, further comprising:
a backside back-end-of-line metallization structure under the first device layer; and
a frontside back-end-of-line metallization structure over the second device layer.

20. The semiconductor structure of claim 18, further comprising a via connecting the uppermost interconnect wiring level to at least one other remaining interconnect wiring level of the at least three interconnect wiring levels, wherein the at least one other remaining interconnect wiring level is stacked over the lowermost interconnect wiring level and wires of the at least one other remaining interconnect wiring level have a minimum pitch which is the same as the minimum pitch of the wires of the lowermost interconnect wiring level.
